(19) United States
(12) Patent Application Publication
(10) Pub. No.: US 2016/0219239 A1
(43) Pub. Date: Jul. 28, 2016

(54) SOLID-STATE IMAGING DEVICE

(71) Applicant: Kabushiki Kaisha Toshiba, Minato-ku (JP)

(72) Inventor: Shinya ITOH, Oita (JP)

(73) Assignee: Kabushiki Kaisha Toshiba, Minato-ku (JP)

(21) Appl. No.: 15/001,831

(22) Filed: Jan. 20, 2016

(30) Foreign Application Priority Data
Jan. 27, 2015 (JP) 2015-013748

(51) Int. Cl. H04N 5/3745; H04N 5/369

(52) U.S. Cl. CPC H04N 5/37457; H04N 5/3698

(57) ABSTRACT

According to one embodiment, a solid-state imaging device is provided which comprises a photoelectric conversion element, a floating diffusion, a first capacitor, a first terminal, a second capacitor, a comparator, and a second terminal. The first capacitor is connected at one terminal to the floating diffusion. The first terminal is connected to the other terminal of the first capacitor, and a reference voltage of which the voltage value falls to a predetermined minimum and then rises to a predetermined maximum, is inputted to the first terminal. The second capacitor is connected at one terminal to the floating diffusion. The comparator has the other terminal of the second capacitor connected to its input and compares the potential on the floating diffusion and a threshold. The second terminal is connected to the output of the comparator, and the comparing result of the comparator is outputted via the second terminal.

### CROSS-REFERENCE TO RELATED APPLICATIONS

This application is based upon and claims the benefit of priority from Japanese Patent Application No. 2015-013748, filed on Jan. 27, 2015; the entire contents of which are incorporated herein by reference.

### FIELD

Embodiments described herein relate generally to a solid-state imaging device.

### BACKGROUND

There are conventionally known solid-state imaging devices wherein a pixel chip where a plurality of pixel cells that photoelectrically convert incident light into signal charge are arranged and a circuit chip that simultaneously reads pixel signals from all the pixel cells placed in the pixel chip are stacked.

Among those solid-state imaging devices, there is one which comprises an amplifying element to amplify the pixel signal in each pixel cell and a constant current source to supply current to each pixel cell to make the amplifying element operate as a source follower.

This solid-state imaging device needs to supply current from the constant current source to all the pixel cells when simultaneously driving all the pixel cells placed in the pixel chip and thus consumes large electric power.

### BRIEF DESCRIPTION OF THE DRAWINGS

FIG. 1 is a schematic perspective view of a solid-state imaging device according to an embodiment;

FIG. 2 is a schematic cross-sectional view of the solid-state imaging device according to the embodiment;

FIG. 3 is an illustrative diagram showing an example circuit configuration of a pixel cell according to the embodiment;

FIG. 4 is a timing chart showing timings of the operation of the pixel cell according to the embodiment;

FIG. 5 is an illustrative diagram showing an example circuit configuration of a peripheral circuit provided on a circuit chip according to the embodiment;

FIG. 6 is an illustrative diagram for explaining the configuration of a fourth capacitor according to the embodiment;

FIGS. 7A and 7B are illustrative diagrams showing another configuration of the pixel cell according to the embodiment;

FIGS. 8A and 8B are illustrative diagrams showing another configuration of the pixel cell according to the embodiment;

FIGS. 9A and 9B are illustrative diagrams showing another configuration of the pixel cell according to the embodiment; and

FIG. 10 is an illustrative diagram showing schematically example placement in the pixel cell according to the embodiment.

### DETAILED DESCRIPTION

According to the present embodiment, a solid-state imaging device is provided which comprises a photoelectric conversion element, a floating diffusion, a first capacitor, a first terminal, a second capacitor, a comparator, and a second terminal. The photoelectric conversion element converts incident light into signal charge. The floating diffusion holds the signal charge transferred from the photoelectric conversion element. The first capacitor is connected at one terminal to the floating diffusion. The first terminal is connected to the other terminal of the first capacitor, and a reference voltage of which the voltage value falls to a predetermined minimum and then rises to a predetermined maximum, is inputted to the first terminal. The second capacitor is connected at one terminal to the floating diffusion. The comparator has the other terminal of the second capacitor connected to its input and compares the potential on the floating diffusion and a threshold. The second terminal is connected to the output of the comparator, and the comparing result of the comparator is outputted via the second terminal.

The solid-state imaging device according to an embodiment will be described in detail below with reference to the accompanying drawings. The present invention is not limited to this embodiment.

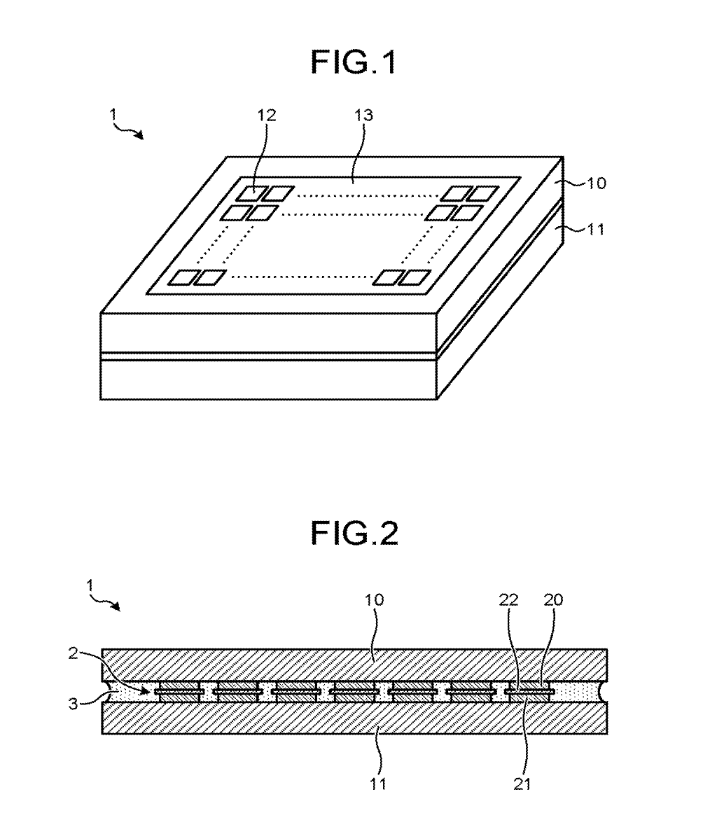

FIG. 1 is a schematic perspective view of a solid-state imaging device 1 according to the embodiment, and FIG. 2 is a schematic cross-sectional view of the solid-state imaging device 1 according to the embodiment. As shown in FIG. 1, the solid-state imaging device 1 comprises a pixel chip 10 and a circuit chip 11 stacked one over the other.

The pixel chip 10 comprises a pixel array 13 wherein multiple pixel cells 12 corresponding to the pixels of a picked-up image are arranged in a two-dimensional array (matrix) along a horizontal direction (row direction) and a vertical direction (column direction), and so on. The circuit chip 11 comprises a logic circuit that reads a pixel signal of the picked-up image from each pixel cell 12 and that performs a variety of signal processing on the read pixel signals, and so on.

Further, as shown in FIG. 2, the solid-state imaging device 1 comprises connection units 2 that electrically connect the pixel chip 10 and the circuit chip 11 and an insulating adhesive member 3 that sticks the pixel chip 10 and the circuit chip 11 together. The connection unit 2 comprises an output terminal 20 provided on the side opposite to the light-incident side of the pixel chip 10, an input terminal 21 provided on the side opposite the pixel chip 10 of the circuit chip 11, and a bump 22 that electrically connects these terminals.

Each pixel cell 12 placed in the pixel chip 10 photoelectrically converts incident light to output a pixel signal corresponding to signal charge obtained by photoelectrical conversion to the circuit chip 11 via the connection unit 2.

This solid-state imaging device 1 simultaneously drives all the pixel cells 12 placed in the pixel chip 10 to simultaneously output the pixel signals of the pixel cells 12 to the circuit chip 11 via the connection units 2.

A solid-state imaging device having a usual pixel chip and circuit chip stacked comprises an amplifying element to amplify the pixel signal in each pixel cell placed in the pixel chip and a constant current source to supply current to each pixel cell to make the amplifying element operate as a source follower.

This solid-state imaging device supplies current from the constant current source to all the pixel cells when simultaneously driving all the pixel cells placed in the pixel chip and thus consumes large electric power.

Hence, as to the solid-state imaging device 1 according to the embodiment, by implementing tactics in the circuit configuration of each pixel cell 12, power consumption when all the pixel cells 12 are simultaneously driven is reduced.

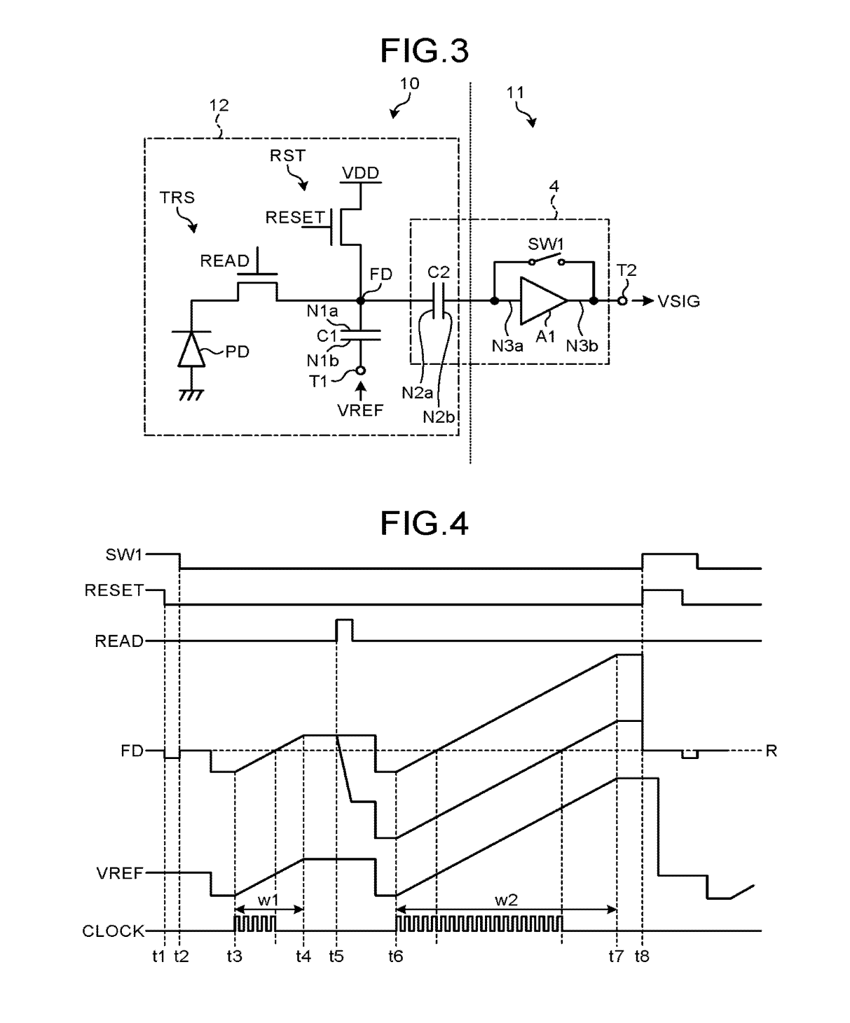

The circuit configuration and operation of the pixel cell 12 according to the embodiment that enables a reduction in power consumption will be described specifically with reference to FIGS. 3 and 4. Since each pixel cell 12 of the solid-state imaging device 1 has the same circuit configuration, one pixel cell 12 will be described here.

FIG. 3 is an illustrative diagram showing an example circuit configuration of the pixel cell 12 according to the embodiment. As shown in FIG. 3, the pixel chip 10 comprises the pixel cell 12, and the circuit chip 11 comprises an inverter A1, a switch SW1, and a second terminal T2. The dotted line in FIG. 3 indicates the boundary between the pixel chip 10 and the circuit chip 11, and the pixel chip 10 is shown to be on one side of the dotted line while the circuit chip 11 is on the other side of the dotted line.

As shown in FIG. 3, the pixel cell 12 comprises a photodiode PD, a transfer transistor TRS, and a reset transistor RST. Further, the pixel cell 12 comprises a floating diffusion FD, a first capacitor C1, and a second capacitor C2.

The photodiode PD is connected at the cathode to ground and at the anode to the source of the transfer transistor TRS. The transfer transistor TRS is connected at the drain to the floating diffusion FD. The reset transistor RST is connected at the source to the floating diffusion FD and at the drain to a power supply voltage line VDD.

The floating diffusion FD is connected to one terminal N1a of the first capacitor C1 and one terminal N2a of the second capacitor C2. The other terminal Nib of the first capacitor C1 is connected to a first terminal T1. A reference voltage VREF generated by a reference voltage generating circuit (not shown) is inputted to the first terminal T1. The reference voltage VREF is in the form of, e.g., a ramp wave whose voltage value increases or decreases over time.

The other terminal N2b of the second capacitor C2 is connected to the input terminal N3a of the inverter A1. The switch SW1 is connected in parallel with the inverter A1. The output terminal N3b of the inverter A1 is connected to a second terminal T2. In this embodiment, the second capacitor C2, inverter A1, and switch SW1 form a chopper comparator 4. Further, in this embodiment, the inverter A1 and switch SW1 from among the constituents of the chopper comparator 4 are provided on the circuit chip 11.

The transfer transistor TRS transfers signal charge photoelectrically converted into by the photodiode PD to the floating diffusion FD when a transfer signal READ is inputted to its transfer gate. The reset transistor RST resets the potential on the floating diffusion FD to the potential of the power supply voltage when a reset signal RESET is inputted to its gate.

When the reference voltage VREF inputted via the first terminal T1 is applied to the first capacitor C1, the potential on the floating diffusion FD changes in tune with the reference voltage VREF. The chopper comparator 4 holds the potential on the floating diffusion FD reset by the reset transistor RST as a threshold and performs comparing operation based on this threshold and the changing potential on the floating diffusion FD. The chopper comparator 4 outputs a pixel signal VSIG that is the comparing result via the second terminal T2.

Next, the operation of the above pixel cell 12 will be described in detail according to the timing chart shown in FIG. 4. FIG. 4 is a timing chart showing timings of the operation of the pixel cell 12 according to the embodiment. The solid-state imaging device 1 picks up an image according to a so-called global shutter method, by which all the pixels are exposed simultaneously, to store signal charge in the photodiodes PD by this exposure.

Here, assume that after at time t1 the reset transistor RST is turned off, at time t2 the switch SW1 is turned off and that thereafter at time t5 the transfer transistor TRS is turned on. Further assume that at time t8 the reset transistor RST and the switch SW1 are turned on. Note that the timing chart shown in FIG. 4 is illustrative.

First, as shown in FIG. 4, when the reset signal RESET falls at time t1, the potential on the floating diffusion FD falls from the potential of the power supply voltage by an amount corresponding to reset noise. In this embodiment, the power supply voltage is, for example, 3.4 V.

Then when at time t2 the switch SW1 is turned off, the floating diffusion FD returns to the potential of the power supply voltage by zero offset operation. The chopper comparator 4 holds a potential that is the same as the potential of the power supply voltage as a reference potential R because of zero offset operation.

Then the potential on the floating diffusion FD changes in tune with the reference voltage VREF because the reference voltage VREF inputted via the first terminal T1 is applied to the first capacitor C1. This reference voltage VREF is a voltage whose maximum and minimum are preset such that the changing potential on the floating diffusion FD intersects with the reference potential R.

Then as the reference voltage VREF falls to the minimum, the potential on the floating diffusion FD falls by an amount corresponding to the voltage of the minimum. Then when the reference voltage VREF starts rising at time t3, the potential on the floating diffusion FD rises in tune with it. Accordingly the chopper comparator 4 determines whether to continue or stop updating the count value at a clock (CLOCK) since time t3. Then the chopper comparator 4 performs comparison based on the changing potential on the floating diffusion FD held on the one terminal N2a of the second capacitor C2 and the reference potential R held on the other terminal N2b of the second capacitor C2. Here, the reference voltage VREF rises from a state where the signal level is low to a high state during first period W1 from time t3 to time t4. That is, the reference voltage VREF takes the minimum voltage value at time t3 in the first period W1 and the maximum voltage value at time t4. In this embodiment, the count of clocks is performed by the reference voltage generating circuit (not shown), and the clock count value is held in a memory unit described later. That is, the chopper comparator 4 determines whether to continue or stop updating the count value in the memory unit.

Then the chopper comparator 4 repeatedly determines to make it continue updating the count value at a clock until the potential on the floating diffusion FD reaches the same potential as the reference potential R as shown in FIG. 4. In this example, at a count of five, the potential on the floating diffusion FD reaches the same potential as the reference potential R.

When the potential on the floating diffusion FD reaches the reference potential R, the chopper comparator 4 determines to stop it updating the count value at a clock. The count number in this first period W1 is a criterion for determination whether signal charge is stored in the photodiodes PD. After reaching the reference potential R, the potential on the floating diffusion FD rises to the maximum at time t4 in tune with the reference voltage VREF.

Then in the pixel cell 12, when the transfer signal READ rises at time t5, the transfer signal READ is inputted to the transfer gate of the transfer transistor TRS. Then in the pixel cell 12, if signal charge is stored in the photodiode PD, signal charge in the photodiode PD is transferred to the floating diffusion FD.

Thus, as shown in FIG. 4, the potential on the floating diffusion FD falls by an amount corresponding to the amount of signal charge stored in the photodiode PD and becomes stable. Then as the reference voltage VREF falls to the minimum again, the potential on the floating diffusion FD falls by an amount corresponding to the voltage of the minimum because the reference voltage VREF inputted via the first terminal T1 is applied to the first capacitor C1.

As the reference voltage VREF starts rising at time t6, the potential on the floating diffusion FD rises in tune with it. Accordingly the chopper comparator 4 determines whether to continue or stop updating the count value at a clock since time t6. Then the chopper comparator 4 performs comparison based on the changing potential on the floating diffusion FD held on the one terminal N2a of the second capacitor C2 and the reference potential R held on the other terminal N2b of the second capacitor C2. Here, the reference voltage VREF rises from a state where the signal level is low to a high state during second period W2 from time t6 to time t7. That is, the reference voltage VREF takes the minimum voltage value at time t6 in the second period W2 and the maximum voltage value at time t7.

Further, the gradient at which the reference voltage VREF rises is the same during the first period W1 and second period W2. In the pixel cell 12, the second period W2 is set longer in time length than the first period W1 so that the potential on the floating diffusion FD, which has fallen by an amount corresponding to the amount of signal charge, intersects with the reference potential R. Thus, the voltage value of the reference voltage VREF is greater at time t7 than at time t4.

Then the chopper comparator 4 repeatedly determines to make it continue updating the count value at a clock until the potential on the floating diffusion FD reaches the same potential as the reference potential R as shown in FIG. 4. In this example, at a count of 19, the potential on the floating diffusion FD reaches the same potential as the reference potential R.

When the potential on the floating diffusion FD reaches the reference potential R, the chopper comparator 4 determines to stop it updating the count value at a clock. After reaching the reference potential R, the potential on the floating diffusion FD rises to the maximum at time t7 in tune with the reference voltage VREF.

Then in the pixel cell 12, when the reset signal RESET rises at time t8, the reset signal RESET is inputted to the gate of the reset transistor RST, so that the potential on the floating diffusion FD is reset to the potential of the power supply voltage. When the switch SW1 is turned on at time t8 simultaneously, the potential on the second capacitor C2 is reset. Then signal charge stored in the photodiode PD by the next exposure is transferred according to the same procedure as above.

In contrast, in the pixel cell 12, as shown in FIG. 4, if signal charge is not stored in the photodiode PD, when the transfer signal READ rises at time t5, the potential on the floating diffusion FD does not fall but stays stable in tune with the reference voltage VREF because the voltage value thereof is stable.

Then as the reference voltage VREF falls to the minimum, the potential on the floating diffusion FD falls by an amount corresponding to the voltage of the minimum. As the reference voltage VREF starts rising at time t6, the potential on the floating diffusion FD rises in tune with it. Accordingly the chopper comparator 4 determines whether to continue or stop updating the count value at a clock since time t6. Then the chopper comparator 4 repeatedly determines to make it continue updating the count value at a clock until the potential on the floating diffusion FD reaches the same potential as the reference potential R. In this example, at a count of five, the potential on the floating diffusion FD reaches the same potential as the reference potential R. This count number is the same as the count number taken in the first period W1. Thus, the solid-state imaging device 1 determines that signal charge was not stored in the photodiode PD on the ground that the count number taken in the second period W2 coincides with the count number taken in the first period W1.

In the circuit chip 11, the pixel signal VSIG of one bit per one count that is the comparing result of the chopper comparator 4 is sequentially outputted via the second terminal T2 connected to the other terminal N3b of the inverter A1.

The pixel cell 12 according to the above embodiment comprises the photodiode PD that converts incident light into signal charge and the floating diffusion FD that holds signal charge transferred from the photodiode PD. The pixel cell 12 further comprises the first capacitor C1 whose one terminal N1a is connected to the floating diffusion FD and the second capacitor C2 whose one terminal N2a is connected to the floating diffusion FD. Further the pixel cell 12 comprises the first terminal T1 connected to the other terminal N1b of the first capacitor C1 and to which the reference voltage VREF is inputted. The second capacitor C2 is a constituent of the chopper comparator 4.

Thus, in this pixel cell 12, the reference voltage VREF is applied to the first capacitor C1, and the potential on the floating diffusion FD changes in tune with the reference voltage VREF. Further, the pixel cell 12 has the chopper comparator 4 perform comparison based on the changing potential on the floating diffusion FD held on the one terminal N2a of the second capacitor C2 and the reference potential R held on the other terminal N2b of the second capacitor C2.

That is, this pixel cell 12 does not amplify the potential on the floating diffusion FD by source follower operation to AD convert the amplified current but makes the potential on the floating diffusion FD attuned to the reference voltage VREF and compares that potential with the reference potential R, thereby performing AD conversion. Hence, the pixel cell 12 does not need a constant current source to read by a source follower, so that it can be driven with less power.

Thus, the power consumption of the solid-state imaging device 1 according to the above embodiment when all the pixel cell 12 arranged in the pixel chip 10 are driven simultaneously can be reduced. The power consumption of this solid-state imaging device 1 can be reduced also in the case where the pixel array 13 is divided into multiple areas and where multiple pixel cells 12 in each area are driven simultaneously.

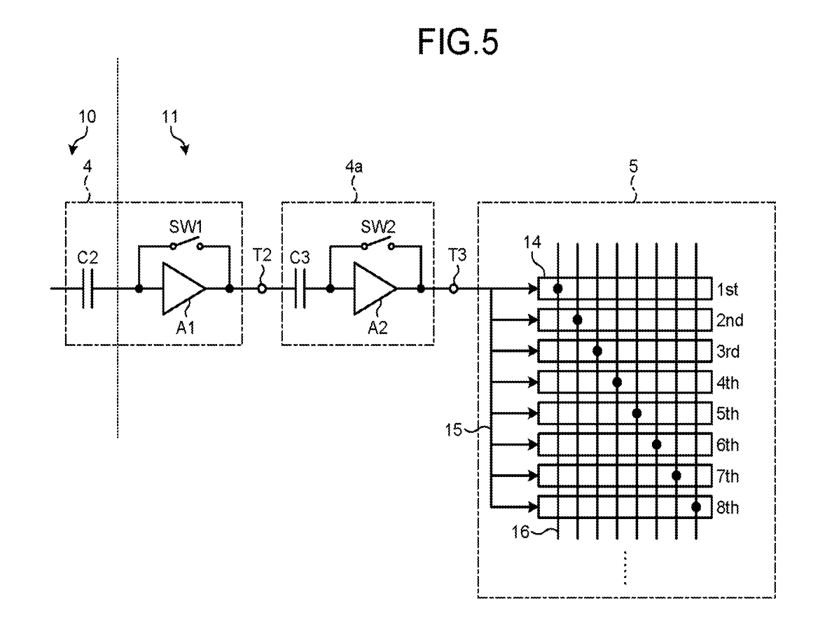

Next, the operation of storing the clock count value into the memory unit will be described with reference to FIG. 5. FIG. 5 is an illustrative diagram showing an example circuit configuration of a logic circuit provided on the circuit chip 11 according to the embodiment. The same reference numerals as in FIG. 3 are used to denote constituents having the same functions as those shown in FIG. 3, with description thereof being omitted. The dotted line in FIG. 5 indicates the boundary between the pixel chip 10 and the circuit chip 11, and the pixel chip 10 is shown to be on one side of the dotted line while the circuit chip 11 is on the other side of the dotted line.

As shown in FIG. 5, the circuit chip 11 comprises the inverter A1 and switch SW1 that are constituents of the chopper comparator 4, the second terminal T2, a chopper comparator 4a that amplifies the pixel signal VSIG outputted via the second terminal T2, and a third terminal T3. The chopper comparator 4a has the same configuration as the chopper comparator 4 in this embodiment and comprises an inverter A2, a switch SW2, and a third capacitor C3.

Further the circuit chip 11 comprises the memory unit 5 connected to the third terminal T3. The memory unit 5 comprises a plurality of SRAMs (Static Random Access Memories) 14, a signal line 15, and a plurality of bus lines 16. Although in this embodiment the SRAMs 14 are used in the memory unit 5, not being limited to this, a DRAM (Dynamic Random Access Memory), FRAM (registered trademark) (Ferroelectric Random Access Memory), or the like can be used instead of the SRAM 14.

The SRAM 14 is a line memory to hold for each bus line 16. The signal line 15 connects the third terminal T3 and the SRAMs 14. The signal line 15 is a write enable signal line of the SRAMs 14 for controlling whether to continue or stop updating the count value in count operation. The bus lines 16 connect to the bit input terminals of each SRAM 14. The count value of N bits (N is a natural number), which is updated per one count, is inputted onto the bus lines 16 in count operation, and the count value of N bits held in the SRAM 14 is outputted in read operation.

In the solid-state imaging device 1, the count value of N bits at the time at which the potential on the floating diffusion FD reaches the reference potential R is stored into each memory unit 5. In this embodiment, as shown in FIG. 5, the solid-state imaging device 1 comprises eight SRAMs 14 in each memory unit 5, which store the count value of 8 bits. Specifically, if the clock count number at the time at which the potential on the floating diffusion FD reaches the reference potential R is 63, the solid-state imaging device 1 stores a count value of 00011111 into the memory unit 5. If the clock count number at the time at which the potential on the floating diffusion FD reaches the reference potential R is 255, the solid-state imaging device 1 stores a count value of 11111111 into the memory unit 5.

The solid-state imaging device 1 according to the above embodiment comprises a plurality of the memory units 5 on the circuit chip 11 respectively corresponding to the pixel cells 12. Each memory unit 5 stores the count value of N bits at the time at which the potential on the floating diffusion FD reaches the reference potential R.

Thus, because the solid-state imaging device 1 need not secure a placement area for the memory unit 5 on the pixel chip 10, the image pickup area on the pixel chip 10 can be expanded, so that more pixel cells 12 are arranged on the pixel chip 10.

Although the solid-state imaging device 1 according to the above embodiment has the configuration where the chopper comparator 4a that amplifies the pixel signal VSIG outputted from the inverter A1 is provided between the second terminal T2 and the third terminal T3, the invention is not limited to this configuration.

For example, in the solid-state imaging device 1, the memory unit 5 may be connected to the second terminal T2 so as to output the pixel signal VSIG directly from the inverter A1 via the second terminal T2 without using the chopper comparator 4a that amplifies the pixel signal VSIG. Or in the solid-state imaging device 1, an additional chopper comparator may be provided at the stage subsequent to the chopper comparator 4a to further amplify the pixel signal VSIG to output via the third terminal T3.

Although the solid-state imaging device 1 according to the above embodiment has the configuration where the second capacitor C2, a constituent of the chopper comparator 4, is provided on the pixel chip 10, the invention is not limited to this configuration. For example, the solid-state imaging device 1 may be configured such that the second capacitor C2, a constituent of the chopper comparator 4, is provided on the circuit chip 11. In this case, the pixel cell 12 comprises the photodiode PD, transfer transistor TRS, reset transistor RST, floating diffusion FD, and first capacitor C1. As the first capacitor C1, second capacitor C2, and third capacitor C3, for example, MOS (Metal Oxide Semiconductor) capacitance elements or MIM (Metal Insulator Metal) capacitance elements are used.

Further, the solid-state imaging device 1 may be configured such that the connection unit 2 electrically connecting the pixel chip 10 and the circuit chip 11 functions as a fourth capacitor C4. This fourth capacitor C4 is a constituent of the chopper comparator 4. That is, the fourth capacitor C4 corresponds to the second capacitor C2 of the above chopper comparator 4. In this case, an MIM capacitance element is used as the fourth capacitor C4.

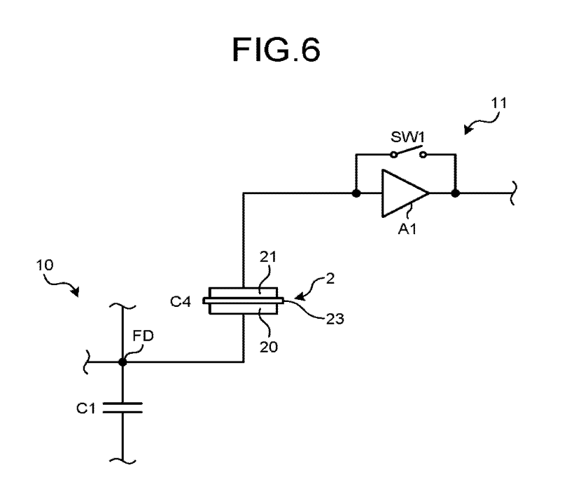

Here, the configuration where the connection unit 2 functions as the fourth capacitor C4, an MIM capacitance element, will be described with reference to FIG. 6. FIG. 6 is an illustrative diagram for explaining the configuration of the fourth capacitor C4 according to the embodiment. The same reference numerals as in FIGS. 2 and 3 are used to denote constituents having the same functions as those shown in FIGS. 2 and 3, with description thereof being omitted.

As shown in FIG. 6, the connection unit 2 comprises an insulating member 23 instead of the conductive bump 22 so as to function as the fourth capacitor C4, an MIM capacitance element. Thus, the connection unit 2 has a structure in which the insulating member 23 is sandwiched between the output terminal 20 and input terminal 21 made of metal, that is, an MIM structure. Hence, the connection unit 2 functions as an MIM capacitance element.

In the solid-state imaging device 1 according to the above embodiment, because the connection unit 2 connecting the pixel chip 10 and the circuit chip 11 functions as the fourth capacitor C4 that is a constituent of the chopper comparator 4, the size of the pixel chip 10 and the circuit chip 11 can be reduced.

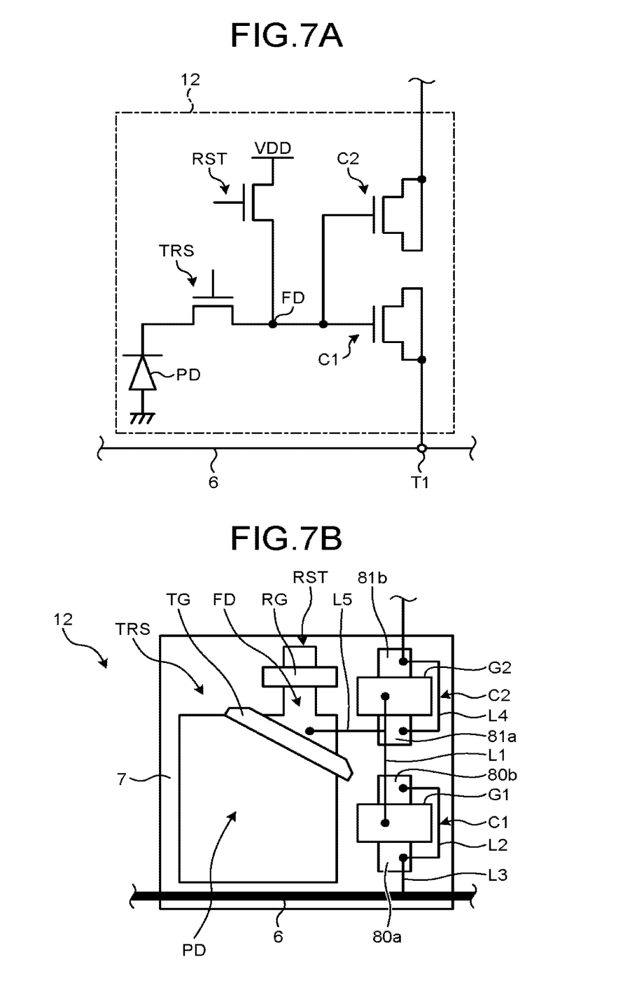

Next, the specific structure of each pixel cell 12 placed on the pixel chip 10 will be described with reference to FIGS. 7A to 10. Because each pixel cell 12 has the same structure, one pixel cell 12 will be described here. The same reference numerals as in FIG. 3 are used to denote constituents having the same functions as those shown in FIG. 3, with description thereof being omitted.

FIGS. 7A and 7B are illustrative diagrams showing another configuration of the pixel cell 12 according to the embodiment. Specifically, FIG. 7A is an illustrative diagram showing the circuit configuration of the pixel cell 12 where MOS capacitance elements are used according to the embodiment. FIG. 7B is an illustrative diagram showing schematically the placement in the pixel cell 12 shown in FIG. 7A in top plan view.

As shown in FIG. 7A, the pixel cell 12 comprises the first capacitor C1 that is a MOS capacitance element and the second capacitor C2 that is a MOS capacitance element. The pixel cell 12 is connected via the first terminal T1 to a reference signal line 6 over which the reference voltage VREF is transmitted. In FIG. 7A, the connection relation between the photodiode PD, floating diffusion FD, transfer transistor TRS, reset transistor RST, first capacitor C1, and second capacitor C2 is the same as the connection relation in the pixel cell 12 shown in FIG.

As shown in FIG. 7B, the pixel cell 12 comprises the photodiode PD (a photoelectric conversion element) and the floating diffusion FD that are electrically element-separated. The transfer gate TG of the transfer transistor TRS is placed over part of a semiconductor layer 7 between the photodiode PD and the floating diffusion FD. The gate RG of the reset transistor RST is placed over part of the semiconductor layer 7 next to the floating diffusion FD.

Further, the gate electrode G1 of the first capacitor C1 that is a MOS capacitance element and the gate electrode G2 of the second capacitor C2 that is a MOS capacitance element are placed over an area of the semiconductor layer 7 adjacent to the photodiode PD. The gate electrode G1 is located between a source region 80a and drain region 80b formed in the semiconductor layer 7. The gate electrode G2 is located between a source region 81a and drain region 81b formed in the semiconductor layer 7. Further, the reference signal line 6 is placed over an area of the semiconductor layer 7 adjacent to the photodiode PD and the first capacitor C1 that are in a line.

The gate electrodes G1 and G2 are electrically connected by a metal line L1. The source region 80a and the drain region 80b are electrically connected by a metal line L2. The source region 80a and the reference signal line 6 are electrically connected by a metal line L3. The source region 81a and the drain region 81b are electrically connected by a metal line L4. The floating diffusion FD and the metal line L1 are electrically connected by a metal line L5.

As such, in the case of using MOS capacitance elements, the pixel cell 12 has the photodiode PD, floating diffusion FD, transfer gate TG, gate RG, and gate electrodes G1, G2 placed in and over the semiconductor layer 7.

In the solid-state imaging device 1 according to the above embodiment, because the first capacitor C1 and second capacitor C2 that the pixel cell 12 comprises are MOS capacitance elements, the capacitors can be easily mounted on the semiconductor layer 7, so that the size of the pixel cell 12 can be reduced.

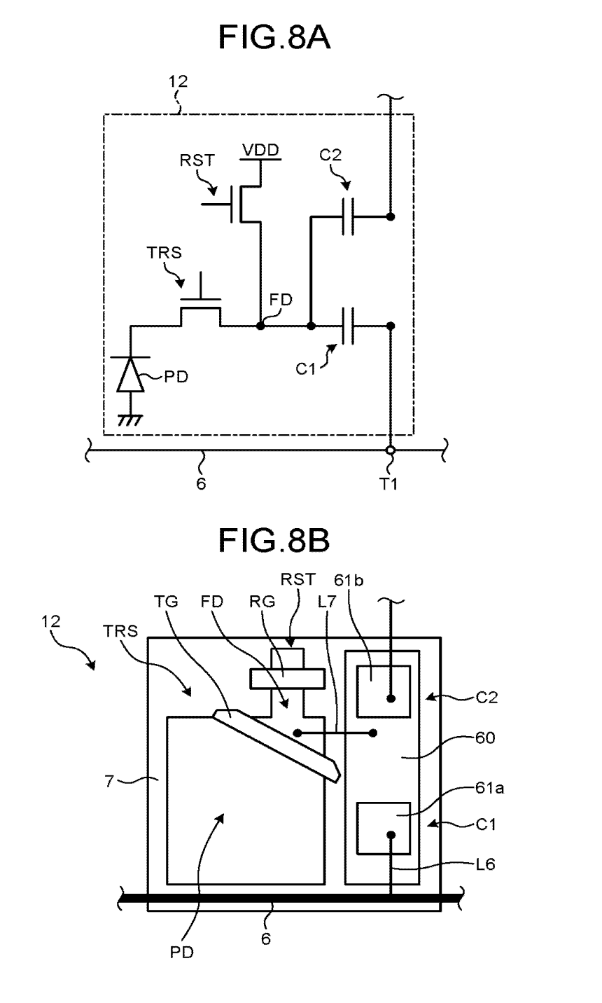

FIGS. 8A and 8B are illustrative diagrams showing another configuration of the pixel cell 12 according to the embodiment. Specifically, FIG. 8A is an illustrative diagram showing the circuit configuration of the pixel cell 12 where MIM capacitance elements are used according to the embodiment. FIG. 8B is an illustrative diagram showing schematically the placement in the pixel cell 12 shown in FIG. 8A in top plan view. The same reference numerals as in FIGS. 7A and 7B are used to denote constituents having the same functions as those shown in FIGS. 7A and 7B, with description thereof being omitted.

As shown in FIG. 8A, the pixel cell 12 comprises the first capacitor C1 that is an MIM capacitance element and the second capacitor C2 that is an MIM capacitance element. The pixel cell 12 is connected via the first terminal T1 to the reference signal line 6 over which the reference voltage VREF is transmitted. In FIG. 8A, the connection relation between the photodiode PD, floating diffusion FD, transfer transistor TRS, reset transistor RST, first capacitor C1, and second capacitor C2 is the same as the connection relation in the pixel cell 12 shown in FIG. 3.

As shown in FIG. 8B, in the pixel cell 12, one common lower-side electrode 60 is placed extending along a width direction of the pixel cell 12 over an area of the semiconductor layer 7 adjacent to the photodiode PD. The upper-side electrode 61a of the first capacitor C1 and the upper-side electrode 61b of the second capacitor C2 are placed over the common lower-side electrode 60. Insulators (not shown) are placed between the upper-side electrodes 61a, 61b and the common lower-side electrode 60.

The upper-side electrode 61a and the reference signal line 6 are electrically connected by a metal line L6. The floating diffusion FD and the common lower-side electrode 60 are electrically connected by a metal line L7.

As such, in the case of using MIM capacitance elements, the pixel cell 12 has the photodiode PD, floating diffusion FD, transfer gate TG, gate RG, common lower-side electrode 60, and upper-side electrodes 61a, 61b placed in and over the semiconductor layer 7.

In the solid-state imaging device 1 according to the above embodiment, because the first capacitor C1 and second capacitor C2 that the pixel cell 12 comprises are MIM capacitance elements, the parasitic capacitance of the capacitors can be reduced, so that the operation speed can be improved.

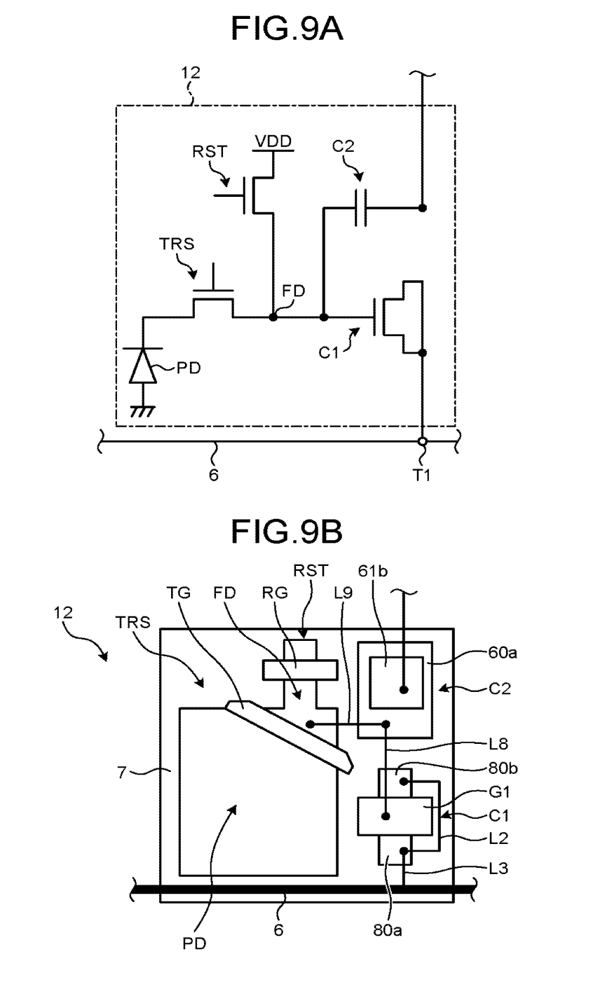

FIGS. 9A and 9B are illustrative diagrams showing another configuration of the pixel cell 12 according to the embodiment. Specifically, FIG. 9A is an illustrative diagram showing the circuit configuration of the pixel cell 12 where a MOS capacitance element and an MIM capacitance element are used according to the embodiment. FIG. 9B is an illustrative diagram showing schematically the placement in the pixel cell 12 shown in FIG. 9A in top plan view. The same reference numerals as in FIGS. 7A, 7B, 8A, and 8B are used to denote constituents having the same functions as those shown in FIGS. 7A, 7B, 8A, and 8B, with description thereof being omitted.

As shown in FIG. 9A, the pixel cell 12 comprises the first capacitor C1 that is a MOS capacitance element and the second capacitor C2 that is an MIM capacitance element. The pixel cell 12 is connected via the first terminal T1 to the reference signal line 6 over which the reference voltage VREF is transmitted. In FIG. 9A, the connection relation between the photodiode PD, floating diffusion FD, transfer transistor TRS, reset transistor RST, first capacitor C1, and second capacitor C2 is the same as the connection relation in the pixel cell 12 shown in FIG. 3.

As shown in FIG. 9B, in the pixel cell 12, the gate electrode G1 of the first capacitor C1 that is a MOS capacitance element and a lower-side electrode 60a are placed in a line along a width direction over an area of the semiconductor layer 7 adjacent to the photodiode PD. The gate electrode G1 is located between the source region 80a and the drain region 80b formed in the semiconductor layer 7. The upper-side electrode 61b of the second capacitor C2, an MIM capacitance element, is placed over the lower-side electrode 60a. An insulator (not shown) is placed between the upper-side electrode 61b and the lower-side electrode 60a.

The gate electrode G1 and the lower-side electrode 60a are electrically connected by a metal line L8. The floating diffusion FD and the lower-side electrode 60a are electrically connected by a metal line L9.

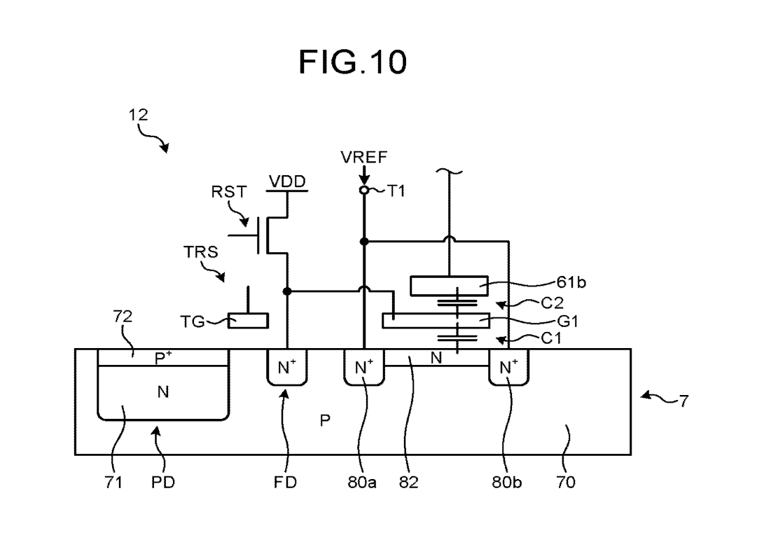

The placement in the semiconductor layer 7 of the pixel cell 12 schematically shown in FIGS. 9A and 9B will be described. FIG. 10 is an illustrative diagram showing schematically example placement in the pixel cell 12 shown in FIGS. 9A and 9B. The same reference numerals as in FIGS. 9A and 9B are used to denote constituents having the same functions as those shown in FIGS. 9A and 9B, with description thereof being omitted.

As shown in FIG. 10, the pixel cell 12 comprises the photodiode PD, the floating diffusion FD, the source region 80a, the drain region 80b, a channel forming region 82, and a dark current suppressing region 72 in the semiconductor layer 7.

The photodiode PD is formed by a PN junction between a P-type Si layer 70 and an N-type Si region 71 formed at a predetermined depth in the P-type Si layer 70. The floating diffusion FD, the source region 80a, and the drain region 80b are formed by ion implanting an N-type impurity of a high concentration into the surface layer of the P-type Si layer 70. The channel forming region 82 is formed by ion implanting an N-type impurity into part of the P-type Si layer 70 between the source region 80a and the drain region 80b. The dark current suppressing region 72 is formed by ion implanting a P-type impurity of a high concentration into part of the surface layer of the P-type Si layer 70 above the photodiode PD.

The transfer gate TG of the transfer transistor TRS located between the photodiode PD and the floating diffusion FD is formed over the surface of the semiconductor layer 7. Further, the gate electrode G1 of the first capacitor C1 located over the channel forming region 82, and the upper-side electrode 61b of the second capacitor C2 located above the gate electrode G1 are formed over the surface of the semiconductor layer 7.

As such, in the case of using a MOS capacitance element and an MIM capacitance element, the pixel cell 12 has the photodiode PD, floating diffusion FD, transfer gate TG, reset gate RG, gate electrode G1, lower-side electrode 60a, and upper-side electrode 61b placed in and over the semiconductor layer 7.

In the solid-state imaging device 1 according to the above embodiment, because the first capacitor C1 and second capacitor C2 that the pixel cell 12 comprises are a MOS capacitance element and an MIM capacitance element, a reduction in the size of the pixel cell 12 and an improvement in the operation speed can be achieved simultaneously.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a photoelectric conversion element that converts incident light into signal charge;
a floating diffusion that holds the signal charge transferred from the photoelectric conversion element;
a first capacitor connected at one terminal to the floating diffusion;
a first terminal connected to the other terminal of the first capacitor and to which is inputted a reference voltage of which the voltage value falls to a predetermined minimum and then rises to a predetermined maximum;
a second capacitor connected at one terminal to the floating diffusion;
a comparator having the other terminal of the second capacitor connected to its input and that compares the potential on the floating diffusion and a threshold; and
a second terminal connected to the output of the comparator and via which the comparing result of the comparator is outputted.

2. The solid-state imaging device according to claim 1, further comprising a reset transistor that resets the signal charge held in the floating diffusion,
wherein the comparator holds the potential on the floating diffusion reset by the reset transistor as the threshold.

3. The solid-state imaging device according to claim 1, wherein the comparator is a chopper comparator which comprises:
an inverter having the other terminal of the second capacitor connected to its input; and
a switch connected in parallel with the inverter.

4. The solid-state imaging device according to claim 1, further comprising a memory unit connected to the second terminal to store the comparing result outputted via the second terminal.

5. The solid-state imaging device according to claim 1, further comprising:
a first substrate where the photoelectric conversion element, the floating diffusion, the first capacitor, the first terminal, and the second capacitor are provided; and
a second substrate stacked on the first substrate and where the comparator and the second terminal are provided.

6. The solid-state imaging device according to claim 5, wherein the first substrate is a pixel chip, and the second substrate is a circuit chip.

7. The solid-state imaging device according to claim 1, further comprising:
a first substrate where the photoelectric conversion element, the floating diffusion, the first capacitor, and the first terminal are provided; and
a second substrate stacked on the first substrate and where the second capacitor, the comparator, and the second terminal are provided.

8. The solid-state imaging device according to claim 7, wherein the first substrate is a pixel chip, and the second substrate is a circuit chip.

9. The solid-state imaging device according to claim 4, further comprising:
an amplifier connected between the second terminal and the memory unit to amplify the comparing result outputted via the second terminal.

10. The solid-state imaging device according to claim 9, wherein the amplifier is a chopper comparator which comprises:
an inverter having the second terminal connected to its input; and
a switch connected in parallel with the inverter.

11. The solid-state imaging device according to claim 1, further comprising:
a first substrate where the photoelectric conversion element, the floating diffusion, the first capacitor, and the first terminal are provided;
a second substrate stacked on the first substrate and where the comparator and the second terminal are provided; and
a connection unit that electrically connects the first substrate and the second substrate,
wherein the connection unit is constituted by the second capacitor that is an MIM (Metal Insulator Metal) capacitance element.

12. The solid-state imaging device according to claim 11, wherein the first substrate is a pixel chip, and the second substrate is a circuit chip.

13. The solid-state imaging device according to claim 4, wherein the memory unit has any one of an SRAM (Static Random Access Memory), DRAM (Dynamic Random Access Memory), and FRAM (Ferroelectric Random Access Memory).

14. The solid-state imaging device according to claim 1, wherein the first capacitor and the second capacitor are MOS (Metal Oxide Semiconductor) capacitance elements.

15. The solid-state imaging device according to claim 1, wherein the first capacitor and the second capacitor are MIM (Metal Insulator Metal) capacitance elements.

16. The solid-state imaging device according to claim 1, wherein the first capacitor is a MOS (Metal Oxide Semiconductor) capacitance element, and the second capacitor is an MIM (Metal Insulator Metal) capacitance element.

17. The solid-state imaging device according to claim 1, wherein the reference voltage is a voltage of a ramp waveform.
